(19) United States
(12) Patent Application Publication
(10) Pub. No.: US 2025/0210431 A1
(43) Pub. Date: Jun. 26, 2025

(54) SEMICONDUCTOR PACKAGE AND MANUFACTURING METHOD THEREOF

(71) Applicant: SAMSUNG ELECTRONICS CO., LTD., SUWON-SI (KR)

(72) Inventor: Jeongki JANG, Suwon-si (KR)

(21) Appl. No.: 18/826,635

(22) Filed: Sep. 6, 2024

(30) Foreign Application Priority Data
Dec. 20, 2023 (KR) 10-2023-0187537
Feb. 22, 2024 (KR) 10-2024-0026098

(51) Int. Cl. H01L 23/31; H01L 21/56; H01L 23/00; H01L 23/538; H01L 25/16

(52) U.S. Cl. CPC H01L 23/3107; H01L 21/56; H01L 23/562; H01L 25/16; H10D 1/68; H01L 23/538

(57) ABSTRACT

A semiconductor package includes: a semiconductor chip and an electronic component mounted on a substrate; and a molding layer disposed on the substrate and covering the semiconductor chip and the electronic component, wherein the electron component includes a plurality of grooves, wherein the plurality of grooves are disposed on a surface of the electronic component, wherein the plurality of grooves have a first width at an entrance portion of the plurality of grooves and a second width greater than the first width below the entrance portion, and wherein the molding layer is disposed in the plurality of grooves.

### CROSS-REFERENCE TO RELATED APPLICATION

This application claims priority under 35 U.S.C. § 119 to Korean Patent Application No. 10-2023-0187537 filed in the Korean Intellectual Property Office on Dec. 20, 2023, and Korean Patent Application No. 10-2024-0026098 filed in the Korean Intellectual Property Office on Feb. 22, 2024, the disclosures of which are incorporated by reference herein in their entireties.

### TECHNICAL FIELD

The present inventive concept relates to a semiconductor package and a method for manufacturing the same.

### DISCUSSION OF THE RELATED ART

Generally, a semiconductor package may include a semiconductor chip and electronic components, and the semiconductor chip and electronic components may be protected by a molding layer.

When stress or a force is applied to the semiconductor package from the outside, the molding layer may peel off from the electronic component, and the quality of the electronic component may deteriorate due to the peeling of the molding layer.

### SUMMARY

According to an embodiment of the present inventive concept, a semiconductor package includes: a semiconductor chip and an electronic component mounted on a substrate; and a molding layer disposed on the substrate and covering the semiconductor chip and the electronic component, wherein the electron component includes a plurality of grooves, wherein the plurality of grooves are disposed on a surface of the electronic component, wherein the plurality of grooves have a first width at an entrance portion of the plurality of grooves and a second width greater than the first width below the entrance portion, and wherein the molding layer is disposed in the plurality of grooves.

According to an embodiment of the present inventive concept, a semiconductor package manufacturing method includes: forming an electronic component; forming a plurality of grooves on a surface of the electronic component; mounting a semiconductor chip and the electronic component on the substrate; and forming, on the substrate, a molding layer covering the semiconductor chip and the electronic component, wherein the plurality of grooves have a first width at an entrance portion of the grooves and a second width greater than the first width, and the molding layer is formed in the plurality of grooves.

### BRIEF DESCRIPTION OF THE DRAWINGS

FIG. 1 is a cross-sectional view of a semiconductor package according to an embodiment of the present inventive concept.

FIG. 2 is a top plan view of an electronic component of a semiconductor package according to an embodiment of the present inventive concept.

FIG. 3 is a cross-sectional view illustrating a portion of an electronic component of a semiconductor package according to an embodiment of the present inventive concept.

FIG. 4 is a cross-sectional view illustrating a part of an electronic component of a semiconductor package according to an embodiment of the present inventive concept.

FIG. 5 is a cross-sectional view illustrating a portion of an electronic component of a semiconductor package according to an embodiment of the present inventive concept.

FIG. 6 is a plan view illustrating a method of manufacturing an electronic component of a semiconductor package according to an embodiment of the present inventive concept.

FIGS. 7, 8 and 9 are cross-sectional views illustrating a method of manufacturing an electronic component of a semiconductor package according to an embodiment of the present inventive concept.

FIGS. 10 and 11 are cross-sectional views illustrating a method of manufacturing an electronic component of a semiconductor package according to an embodiment of the present inventive concept.

### DETAILED DESCRIPTION OF THE EMBODIMENTS

Hereinafter, with reference to accompanying drawings, various embodiments of the present inventive concept will be described in detail so that a person of an ordinary skill in the art can implement the present inventive concept. The embodiments of the present inventive concept may be implemented in many different forms, and the present inventive concept is not limited to the embodiments described herein.

Identical or similar components are assigned the same reference numerals throughout the specification and drawings, and thus, redundant descriptions may be omitted or briefly discussed.

In addition, the attached drawings are for easily understanding the embodiments disclosed in this specification. It should be understood that the technical idea disclosed in this specification is not limited by the attached drawings, and includes all of modifications, substitutes and equivalents included in the spirit and technical scope of this disclosure.

In the drawings, various thicknesses, lengths, and angles are shown and while the arrangement shown does indeed represent an embodiment of the present inventive concept, it is to be understood that modifications of the various thicknesses, lengths, and angles may be possible within the spirit and scope of the present inventive concept and the present inventive concept is not necessarily limited to the particular thicknesses, lengths, and angles shown.

It will be understood that when an element such as a layer, film, region, or substrate is referred to as being “on” another element, it can be directly on the other element or intervening elements may also be present. In contrast, when an element is referred to as being “directly on” another element, there are no intervening elements present therebetween. In addition, being “on” or “above” a reference element means being positioned on or below the reference element, and does not necessarily mean being positioned “above” or “on” in a direction opposite to gravity.

In addition, throughout the specification, when referring to “in a plane view”, it means that the target portion is viewed from above, and when referring to “in a cross-section view”, it means that a cross section of the target portion cut vertically is viewed from a side.

In addition, throughout the specification, when referring to “connected”, it means that two or more components are directly connected, indirectly connected through other components, physically connected, electrically connected, or integrated although referred to by different names depending on location or function.

Hereinafter, various embodiments of the present inventive concept and variations will be described in detail with reference to the drawings.

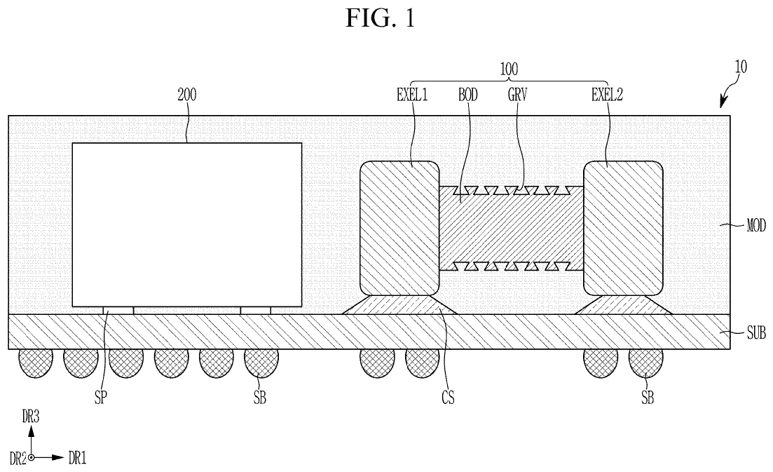

Referring to FIG. 1, a semiconductor package according to an embodiment of the present inventive concept will be described. FIG. 1 is a cross-sectional view of a semiconductor package according to an embodiment of the present inventive concept.

Referring to FIG. 1, the semiconductor package 10 according to an embodiment of the present inventive concept may include a substrate SUB, an electronic component 100 and a semiconductor chip 200 mounted on the substrate SUB, a molding layer MOD disposed on the substrate SUB and at least partially surrounding the semiconductor chip 200, and an external contact terminal SB connected to the substrate SUB and capable of being connected to external devices.

The substrate SUB may extend along a plane where a first direction DR1 and a second direction DR2 intersect each other.

The substrate SUB may be a redistribution substrate, and the substrate SUB may include a plurality of insulating layers. A plurality of redistribution layers and a plurality of vias may be arranged within the plurality of insulating layers.

The insulating layer of the substrate SUB may include an organic material such as a photo-imageable dielectric (PID) material. The photo-imageable dielectric material may be a polymer, and, for example, the photo-imageable dielectric material may include photosensitive polyimide, polybenzoxazole, phenol-based polymer, and benzocyclobutene-based polymer, but not limited thereto.

The electronic component 100 may be disposed on the substrate SUB along a third direction DR3 that is substantially perpendicular to the first direction DR1 and the second direction DR2.

The electronic component 100 may be electrically connected to the substrate SUB through a connection portion CS. Being electrically connected/electrically contacting may include a direct connection/contact or an indirect connection/contact through another conductive component.

The connection portion CS may include a metal such as aluminum.

The electronic component 100 may be a multi-layer ceramic condenser (MLCC).

The electronic component 100 may include a body portion BOD, a first external electrode EXEL1, a second external electrode EXEL2. The first external electrode EXEL1 and second external electrode EXEL2 are disposed on two sides of the body portion BOD along the first direction DR1 and are spaced apart from each other by the body portion BOD.

The electronic component 100 may have a plurality of grooves GRV that are disposed on the surface of the body portion BOD. The plurality of grooves GRV may be disposed on a lower surface and upper surfaces of the body portion BOD along the third direction DR3, but the present inventive concept is not limited thereto, and the plurality of grooves GRV may be disposed not only on the lower and upper surfaces of the body portion BOD, but may also be disposed on a side surface of the body portion BOD.

The semiconductor chip 200 may be disposed on the substrate SUB. The semiconductor chip 200 may be mounted on the substrate SUB through the chip pad SP.

The semiconductor chip 200 may be a memory chip or a logic chip, but the present inventive concept is not limited thereto.

Integrated circuits of the semiconductor chip 200 may include, for example, a memory circuit, a logic circuit, or a combination thereof, but the present inventive concept is not limited thereto.

The chip pad SP may include a metal such as aluminum, but the present inventive concept is not limited thereto.

The molding layer (MOD) may be disposed on the substrate SUB and cover the electronic component 100 and the semiconductor chip 200. The molding layer MOD may be disposed in a gap area that is between the substrate SUB, the electronic component 100, and the semiconductor chip 200 to seal the connection portion CS and the chip pad SP.

The molding layer MOD may include, for example, an insulating polymer such as an epoxy-based molding compound. According to embodiments of the present inventive concept, an underfill pattern may be provided in the gap area that is between the substrate SUB, the electronic component 100, and the semiconductor chip 200.

External contact terminals SB may be disposed on a bottom surface of the substrate SUB.

The external contact terminals SB may include a conductive material such as metal. The external contact terminals SB may include, for example, solder balls or solder bumps.

The semiconductor package 10 may be connected to external devices through the external contact terminals SB.

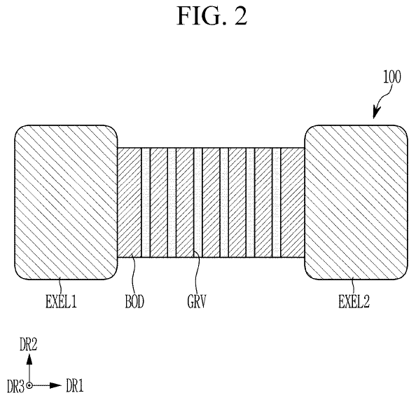

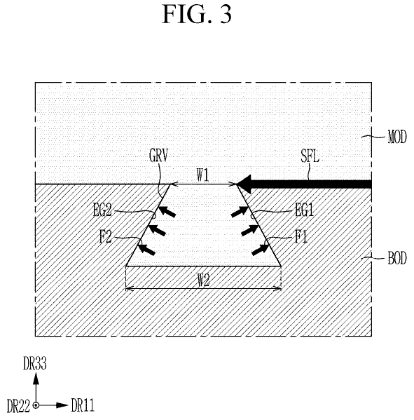

Then, referring to FIGS. 2 and 3, the electronic component 100 of the semiconductor package 10 according to an embodiment of the present inventive concept will be described in more detail. FIG. 2 is a top plan view of an electronic component of a semiconductor package according to an embodiment of the present inventive concept, and FIG. 3 is a cross-sectional view illustrating a portion of an electronic component of a semiconductor package according to an embodiment of the present inventive concept.

Referring to FIG. 1 and FIG. 2, the electronic component 100 of the semiconductor package 10 according to an embodiment of the present inventive concept may include a body portion BOD, a first external electrode EXEL1, and a second external electrode EXEL2. The first external electrode EXEL1 and the second external electrode EXEL2 are disposed on both sides of the body portion BOD along a first direction DR1 and are spaced apart from each other.

A plurality of grooves GRV may be disposed in the body portion BOD of the electronic component 100.

The plurality of grooves GRV may be disposed on a lower surface and an upper surfaces of the body portion BOD along a third direction DR3, but the present inventive concept is not limited thereto, and the plurality of grooves GRV may be disposed not only on the lower and upper surfaces, but also on the sides of the body portion BOD.

A plurality of grooves GRV disposed on the lower and upper surfaces of the body portion BOD may have a shape extending along the second direction DR2, and may be disposed to be spaced apart from each other along the first direction DR1.

When the plurality of grooves GRV are disposed on a side of the body portion BOD, the plurality of grooves GRV may have a shape extending along the third direction DR3 and may be disposed to be spaced from each other along the first direction DR1.

Referring to FIG. 3 along with FIGS. 1 and 2, a width of the groove GRV measured along a horizontal direction DR11 may be greater inside the groove GRV and smaller at an entrance (e.g., an opening) of the groove GRV. For example, the width of the groove GRV may be largest at the bottom surface of the groove GRV. For example, the width of the groove GRV may increase from the entrance of the groove GRV toward the bottom surface of the groove GRV. The horizontal direction DR11 is substantially perpendicular to an extending direction DR22, in which the plurality of grooves GRV extend, and substantially parallel with the surface of the body portion BOD.

When a plurality of grooves GRV are disposed on the upper and lower surfaces of the body portion BOD, the horizontal direction DR11 may be substantially parallel to the first direction DR1, and the extending direction DR22 may be substantially parallel with the second direction DR2. When the plurality of grooves GRV are disposed on a side of the body portion BOD, the extending direction DR22 may be substantially parallel to the third direction DR3.

For example, along a vertical direction DR33 perpendicular to the surface of the body portion BOD, a lower width W2 at the bottom surface of the groove GRV may be greater than an upper width W1 that is at an opening of the groove GRV (e.g., an upper portion of the groove GRV). For example, the upper width W1 may be a width of an entrance of the groove GRV, and the lower width W2 may be a width of a bottom portion of the groove GRV, but the present inventive concept is not limited thereto.

A molding layer MOD may be disposed within the groove GRV of the body portion BOD.

As described above, along the vertical direction DR33 perpendicular to the surface of the body portion BOD, the width of the groove GRV may be smaller at an upper part than at a lower part of the groove GRV.

The groove GRV may include a first side wall EG1 and a second side wall EG2 facing each other along the horizontal direction DR11. The first side wall EG1 and the second side wall EG2 may be sloped walls that are inclined with respect to a surface of the body portion BOD. The first side wall EG1 and the second side wall EG2 may be sloped walls that are inclined in different directions from the surface of the body portion BOD.

The electronic component 100 may be protected by the molding layer MOD, and inside of the groove GRV of the body portion BOD of the electronic component 100 is filled with the molding layer MOD.

When an external force is applied to the semiconductor package 10 or moisture increases, stress at an interface between the electronic component 100 of the semiconductor package 10 and the molding layer MOD may increase, and when the molding layer MOD is peeled off from the electronic component 100, an empty space between the molding layer MOD and the electronic component 100 may be created. Additionally, when the external temperature of the semiconductor package 10 increases, a portion of the metal substance of the connection portion CS for mounting the electronic component 100 may be liquefied. In this way, when the molding layer MOD is peeled off from the electronic component 100, the metal substance of the connection portion CS may be diffused along the empty space that is between the molding layer MOD and the electronic component 100, and a short may be formed between the first external electrode EXEL1 and the second external electrode EXEL2 due to the diffused metal substance. This may cause defects in the semiconductor package 10 including the electronic component 100.

The body portion BOD of the electronic component 100 of the semiconductor package 10 according to an embodiment of the present inventive concept may include a plurality of grooves GRV, and a molding layer MOD may be filled within the plurality of grooves GRV of the body portion BOD. Therefore, the contact area between the body portion BOD and the molding layer MOD can be increased, and thus the contact force between the molding layer MOD and the body portion BOD can be increased, so that delamination of the molding layer MOD from the body portion BOD can be reduced, and even if the metal substance SFL of the connection portion CS moves along the interface between the body portion BOD and the molding layer MOD, the groove GRV of the body portion BOD increases the moving distance of the metal substance SFL and may interfere with the flow of the metal substance SFL.

Moreover, the groove GRV of the body portion BOD of the electronic component 100 of the semiconductor package 10 according to the embodiment may have, along the vertical direction DR33 perpendicular to the surface of the body portion BOD, a greater second width W2 at a lower part and a smaller first width W1 at an upper part. The groove GRV may include a first side wall EG1 and a second side wall EG2, which are sloped walls that face each other along the horizontal direction DR11 and are inclined in opposite directions. For example, the first side wall EG1 and the second side wall EG2 are inclined toward each other.

Even if a force toward the molding layer MOD is applied from outside to peel the molding layer MOD off from the surface of the body portion BOD, inside each groove GRV, forces F1 and F2 from the molding layer MOD to the side walls EG1 and EG2 can be applied. For example, when an external force is applied from the surface of the body portion BOD toward the molding layer MOD, since, inside each groove GRV, a first force F1 from the molding layer MOD to the first side wall EG1 and a second force F2 from the molding layer MOD to the second side wall EG2 are applied, it may be difficult for the molding layer MOD to be peeled off within each groove GRV.

In addition, even if the metal substance SFL of the first external electrode EXEL1, the second external electrode EXEL2 and the electronic component 100 moves along the interface between the body portion BOD and the molding layer MOD, since the second width W2 inside the groove GRV is greater than the first width W1 at the entrance of the groove GRV, the metal substance SFL can remain only inside the groove GRV while passing the groove portion GRV, and it may be difficult to connect to each other passing through the groove GRV. Therefore, the first external electrode EXEL1 and the second external electrode EXEL2 can be prevented from being shorted with each other due to diffusion of the metal substance SFL of the electronic component 100, and the defects in the semiconductor package 10 can be prevented.

As such, according to the semiconductor package 10 according to the embodiment, the body portion BOD of the electronic component 100 of the semiconductor package 10 may include a plurality of grooves GRV, and the molding layer MOD may fill the plurality of groove GRV of the body portion BOD, and the groove GRV may have a greater second width W2 at a bottom of the groove GRV and a smaller first width W1 at an upper part of the groove GRV along the vertical direction DR33 that is substantially perpendicular to the surface of the body portion BOD. Therefore, the molding layer MOD can be prevented from being peeled off from the body portion BOD, and even if the metal substance SFL moves along the interface that is between the body portion BOD and the molding layer MOD, since it may be difficult for the metal substance SFL to connect to each other passing through the groove GRV, the first external electrode EXEL1 and the second can be prevented from being shorted each other.

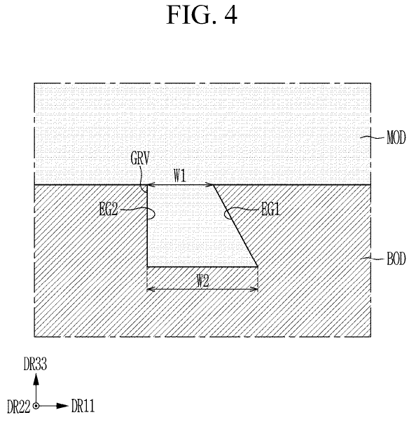

Now, with reference to FIG. 4, the electronic component 100 of the semiconductor package 10 according to an embodiment of the present inventive concept will be described. FIG. 4 is a cross-sectional view illustrating a part of an electronic component of a semiconductor package according to an embodiment of the present inventive concept.

Similar to the embodiment shown in FIGS. 1 and 2, the electronic component 100 of the semiconductor package 10 according to the present embodiment may include a body portion BOD, a first external electrode EXEL1, and a second external electrode EXEL2. The first external electrode EXEL1 and the second external electrode EXEL2 may be disposed on both sides of the body portion BOD along the first direction DR1 and may be spaced apart from each other, and a plurality of grooves GRV may be disposed in the body portion BOD of the electronic component 100.

The plurality of groove GRV may be disposed on the lower and upper surfaces of the body portion BOD along the third direction DR3, but the present inventive concept is not limited thereto, and the plurality of grooves GRV may be disposed not only on the lower and upper surfaces, but also on a side of the body portion BOD.

A plurality of grooves GRV, which are disposed on the lower and upper surfaces of the body portion BOD, may have a shape extending along the second direction DR2 and may be disposed to be spaced apart from each other along the first direction DR1. When the plurality of grooves GRV are disposed on a side of the body portion BOD, the plurality of grooves GRV may have a shape extending along the third direction DR3 and may be disposed to be spaced apart from each other along the first direction DR1.

Referring to FIG. 4 along with FIGS. 1 and 2, a width of the groove GRV measured along a horizontal direction DR11 may be greater inside the groove GRV and smaller at an entrance of the groove GRV. For example, the width of the groove GRV at an upper portion of the groove GRV may be smaller than the width of the groove GRV at a lower portion of the groove GRV. The horizontal direction DR11 is perpendicular to an extending direction DR22, in which the plurality of grooves GRV extend, and substantially parallel with the surface of the body portion BOD.

Along a vertical direction DR33 perpendicular to the surface of the body portion BOD, a lower width W2 at a lower portion of the groove GRV may be greater than an upper width W1 at an upper portion of the groove GRV. For example, the upper width W1 may be a width of an entrance (e.g., an opening) of the groove GRV, and the lower width W2 may be a width of a bottom portion of the groove GRV, but the present inventive concept is not limited thereto.

A molding layer MOD may be disposed within the groove GRV of the body portion BOD.

As described above, along the vertical direction DR33 perpendicular to the surface of the body portion BOD, the width of the groove GRV may be smaller at the upper part than at the lower part of the groove GRV.

The groove GRV may include a first side wall EG1 and a second side wall EG2 facing each other along the horizontal direction DR11.

As shown in FIG. 4, the first side wall EG1 of the groove GRV of the electronic component 100 of the semiconductor package 10 according to the present embodiment may be a sloped wall that is inclined with respect to the surface of the body portion BOD. However, unlike the electronic component 100 of the semiconductor package 10 according to the previously described embodiment, the second side wall EG2 may be substantially perpendicular to the surface of the body portion BOD.

For example, an angle that is formed between the second side wall EG2 of the groove GRV and the bottom surface of the groove GRV is greater than an angle that is formed between the first side wall EG1 of the groove GRV and the bottom surface of the groove GRV.

The electronic component 100 may be protected by the molding layer MOD, and an inside of the groove GRV of the body portion BOD of the electronic component 100 is filled with the molding layer MOD.

The body portion BOD of the electronic component 100 of the semiconductor package 10 according to an embodiment of the present inventive concept may include a plurality of grooves GRV, and a molding layer MOD may fill the plurality of grooves GRV of the body portion BOD. Therefore, the contact area between the body portion BOD and the molding layer MOD can be increased, and thus, the contact force between the molding layer MOD and the body portion BOD can be increased, so that delamination of the molding layer MOD from the body portion BOD can be reduced, and even if the metal substance SFL of the connection portion CS moves along the interface that is between the body portion BOD and the molding layer MOD, the groove GRV of the body portion BOD increases the moving distance of the metal substance SFL and may interfere with the flow of the metal substance SFL.

The groove GRV of the body portion BOD of the electronic component 100 of the semiconductor package 10 according to the embodiment may have, along the vertical direction DR33 that is substantially perpendicular to the surface of the body portion BOD, a greater second width W2 at a lower part and a smaller first width W1 at an upper part that is smaller than the second width W2. Accordingly, even if an external force is applied from the side wall of the groove GRV toward the molding layer MOD, it may be difficult for the molding layer MOD that fills the groove GRV to be peeled off, and even if the metal substance SFL moves along the interface that is between the BOD and the molding layer MOD, since the second width W2 inside the groove GRV is greater than the first width W1 at the entrance of the groove GRV, the metal substance SFL can remain only inside the groove GRV while passing the groove portion GRV, and it may be difficult to connect to each other while passing through the groove GRV. Accordingly, the first external electrode EXEL1 and the second external electrode EXEL2 of the electronic component 100 can be prevented from being shorted to each other, and defects of the semiconductor package 10 including the electronic component 100 can be prevented.

As such, according to the semiconductor package 10 according to the embodiment, the body portion BOD of the electronic component 100 of the semiconductor package 10 may include a plurality of grooves GRV, and the molding layer MOD may fill the plurality of groove GRV of the body portion BOD, and the groove GRV may have a greater second width W2 at a bottom thereof and a smaller first width W1 at an upper part thereof along the vertical direction DR33 substantially perpendicular to the surface of the body portion BOD. Therefore, the molding layer MOD can be prevented from being peeled off from the body portion BOD, and even if the metal substance SFL moves along the interface between the body portion BOD and the molding layer MOD, since it may be difficult for the metal substance SFL to connect to each other while passing through the groove GRV, the first external electrode EXEL1 and the second can be prevented from being shorted to each other.

Many features of the semiconductor package according to the embodiment described above with reference to FIGS. 1 to 3 are all applicable to the semiconductor package according to the present embodiment.

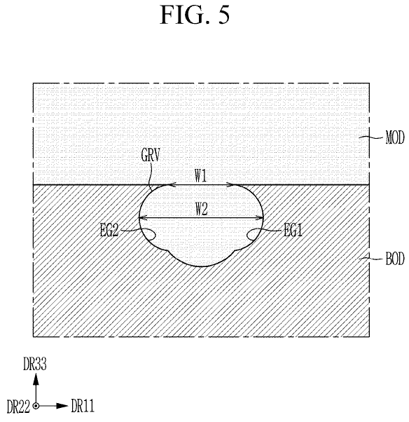

Referring to FIG. 5, the electronic component 100 of the semiconductor package 10 according to an embodiment of the present inventive concept will be described. FIG. 5 is a cross-sectional view illustrating a portion of an electronic component of a semiconductor package according to an embodiment of the present inventive concept.

Similar to the embodiment shown in FIGS. 1 and 2, the electronic component 100 of the semiconductor package 10 according to the present embodiment may include a body portion BOD and a first external electrode EXEL1 and a second external electrode EXEL2, which are disposed on both sides of the body portion BOD along the first direction DR1 and spaced apart from each other, and a plurality of grooves GRV may be disposed in the body portion BOD of the electronic component 100.

The plurality of groove GRV may be disposed on the lower and upper surfaces of the body portion BOD along the third direction DR3, but the present inventive concept is not limited thereto, and the plurality of grooves GRV may be disposed not only on the lower and upper surfaces, but also on a side of the body portion BOD.

A plurality of grooves GRV disposed on the lower and upper surfaces of the body portion BOD may have a shape extending along the second direction DR2 and may be disposed to be spaced apart from each other along the first direction DR1.

When the plurality of grooves GRV are disposed on a side of the body portion BOD, the plurality of grooves GRV may have a shape extending along the third direction DR3 and disposed to be spaced from each other along the first direction DR1.

Referring to FIG. 3 along with FIGS. 1 and 2, a width of the groove measured along a horizontal direction DR11 may be greater inside the groove GRV and smaller at an entrance of the groove GRV. The horizontal direction DR11 is perpendicular to an extending direction DR22, in which the plurality of grooves GRV extend, and substantially parallel with the surface of the body portion BOD.

Along a vertical direction DR33 that is substantially perpendicular to the surface of the body portion BOD, a lower width W2 below the entrance of the groove GRV may be greater than an upper width W1 that is above the lower width W2. For example, the upper width W1 may be a width of an entrance of the groove GRV, and the lower width W2 may be a width of a center portion of the groove GRV, but the present inventive concept is not limited thereto.

A molding layer MOD may be disposed within the groove GRV of the body portion BOD.

As described above, along the vertical direction DR33 that is substantially perpendicular to the surface of the body portion BOD, the width of the groove GRV may be smaller at an upper part than at a lower part of the groove GRV.

The groove GRV may include a first side wall EG1 and a second side wall EG2 facing each other along the horizontal direction DR11.

Unlike the electronic components 100 of the semiconductor package 10 according to embodiments described above, the first sidewall EG1 and the second sidewall EG2 of the groove GRV of the electronic component 100 of the semiconductor package 10 according to the present embodiment may be curved surfaces.

The electronic component 100 may be protected by the molding layer MOD, and an inside of the groove GRV of the body portion BOD of the electronic component 100 is filled with the molding layer MOD.

The body portion BOD of the electronic component 100 of the semiconductor package 10 according to an embodiment of the present inventive concept may include a plurality of grooves GRV, and a molding layer MOD may fill the plurality of grooves GRV of the body portion BOD. Therefore, the contact area between the body portion BOD and the molding layer MOD can be increased, and thus, the contact force between the molding layer MOD and the body portion BOD can be increased, so that delamination of the molding layer MOD from the body portion BOD can be reduced, and even if the metal substance SFL of the connection portion CS moves along the interface that is between the body portion BOD and the molding layer MOD, the groove GRV of the body portion BOD increases the moving distance of the metal substance SFL and may interfere with the flow of the metal substance SFL.

The groove GRV of the body portion BOD of the electronic component 100 of the semiconductor package 10 according to the embodiment may have, along the vertical direction DR33 that is substantially perpendicular to the surface of the body portion BOD, a greater second width W2 at a lower part and a smaller first width W1 at an upper part, and the second width W2 may be greater than the first width W1. Accordingly, even if an external force is applied from the side wall of the groove GRV toward the molding layer MOD, it may be difficult for the molding layer MOD that fills the groove GRV to be peeled off, and even if the metal substance SFL moves along the interface that is between the BOD and the molding layer MOD, since the second width W2 that is inside the groove GRV is greater than the first width W1 that is at the entrance of the groove GRV, the metal substance SFL can remain only inside the groove GRV while passing the groove GRV, and it may be difficult for the metal substance SFL to connect to each other while passing through the groove GRV. Accordingly, the first external electrode EXEL1 and the second external electrode EXEL2 of the electronic component 100 can be prevented from being shorted to each other, and defects of the semiconductor package 10 including the electronic component 100 can be prevented.

As such, according to the semiconductor package 10 according to the embodiment, the body portion BOD of the electronic component 100 of the semiconductor package 10 may include a plurality of grooves GRV, and the molding layer MOD may be disposed within the plurality of groove GRV of the body portion BOD, and the groove GRV may have a greater second width W2 at a bottom and a smaller first width W1, compared to the second width W2, at upper part along the vertical direction DR33 that is substantially perpendicular to the surface of the body portion BOD. Therefore, the molding layer MOD can be prevented from being peeled off from the body portion BOD, and even if the metal substance SFL moves along the interface that is between the body portion BOD and the molding layer MOD, since it may be difficult for the metal substance SFL to connect to each other while passing through the groove GRV, the first external electrode EXEL1 and the second external electrode EXEL 2 can be prevented from being shorted to each other.

Many features of the semiconductor packages according to embodiments of the present inventive concept described above are all applicable to the semiconductor packages according to the present embodiment.

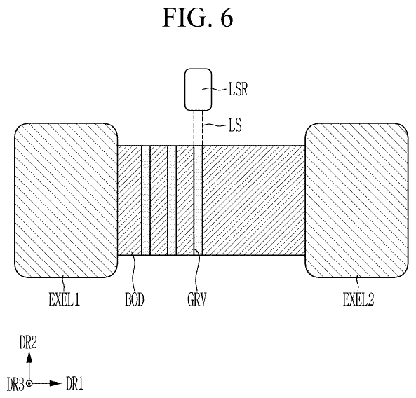

Referring to FIG. 6 along with FIGS. 1 to 3, a method of manufacturing the electronic component 100 of the semiconductor package 10 according to an embodiment of the present inventive concept will be described. FIG. 6 is a plan view illustrating a method of manufacturing an electronic component of a semiconductor package according to an embodiment of the present inventive concept.

First, an electronic component 100 including a body portion BOD, a first external electrode EXEL1 and a second external electrode EXEL2 may be formed. The first external electrode EXEL1 and the second external electrode EXEL2 are disposed on both sides of the body portion BOD along the first direction DR1 and are spaced apart from each other.

Next, a plurality of grooves GRV may be formed in the body portion BOD of the electronic component 100.

Referring to FIG. 6, when forming a plurality of groove GRV in the body portion BOD of the electronic component 100, a plurality of grooves GRV may be formed by emitting the laser LS on a surface of the body portion BOD of the electronic component 100 through a laser supply unit LSR in a direction parallel to a direction in which the plurality of grooves GRV extend.

The laser supply unit LSR may be arranged to be laterally spaced apart from the body unit BOD along a second direction DR2 parallel to the direction in which the plurality of grooves GRV extend, and the laser supply unit LSR may supply the laser LS while moving along the first direction DR1 in which the plurality of grooves GRV is spaced apart. For example, the laser LS may be emitted at certain intervals for predetermined periods so that the plurality of grooves GRV is spaced apart from each other.

The laser LS may be supplied from a side of the body portion BOD toward the surface of the body portion BOD.

The groove GRV may be formed by supplying the laser LS to remove portions of the surface of the body portion BOD.

A portion where the energy of the laser LS is concentrated may be a bottom portion, which has a second width W2, of the groove GRV shown in FIG. 3, and a surface portion of the body part BOD where relatively low laser LS energy is supplied may be an entrance portion, which has a first width W1, of the groove GRV shown in FIG. 3.

In this way, by supplying the laser LS from a side of the body portion BOD toward the surface of the body portion BOD, as shown in FIG. 3, a plurality of grooves GRV having a greater second width W2 at a lower part and a smaller first width W1 at an upper part may be formed along the vertical direction DR33 that is perpendicular to the surface of the body portion BOD.

The electronic component 100, which has a plurality of grooves GRV, and the semiconductor chip 200 may be mounted on the substrate SUB.

A molding layer MOD covering the electronic component 100 and the semiconductor chip 200 may be formed on the substrate SUB on which the electronic component 100 and the semiconductor chip 200 are mounted. The molding layer MOD may fill the plurality of grooves GRV of the body portion BOD.

According to the method of manufacturing a semiconductor package according to an embodiment of the present inventive concept, a plurality of grooves GRV may be formed in the body portion BOD of the electronic component 100 of the semiconductor package 10, and the grooves GRV may have a greater second width W2 at a lower part thereof and a smaller first width W1 at an upper part thereof along the vertical direction DR33 that is substantially perpendicular to the surface of the body portion BOD. The first width W1 is smaller than the second width W2. Therefore, the molding layer MOD can be prevented from being peeled off from the body portion BOD, and even if the metal substance SFL moves along the interface that is between the body portion BOD and the molding layer MOD, since it may be difficult for the metal substance SFL to connect to each other while passing through the groove GRV, the first external electrode EXEL1 and the second external electrode EXEL2 can be prevented from being shorted to each other.

Many features of the semiconductor packages according to the embodiments described above are all applicable to the method of manufacturing a semiconductor package according to the present embodiment.

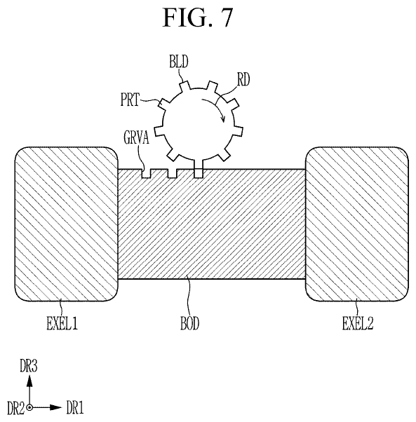

Referring to FIGS. 7 to 9 along with FIGS. 1, 2 and 4, a method of manufacturing the electronic component 100 of the semiconductor package 10 according to an embodiment of the present inventive concept will be described. FIGS. 7 to 9 are cross-sectional views illustrating a method of manufacturing an electronic component of a semiconductor package according to an embodiment of the present inventive concept.

First, an electronic component 100 including a body portion BOD, a first external electrode EXEL1 and a second external electrode EXEL2 may be formed. The first external electrode EXEL1 and the second external electrode EXEL2 may be disposed on both sides of the body portion BOD along the first direction DR1 and spaced apart from each other.

Next, as shown in FIGS. 7 to 9, the plurality of grooves GRV may be formed on a body portion BOD of the electronic component 100.

Referring to FIG. 7, preliminary grooves GRVA may be formed by rotating a first blade BLD having a plurality of protrusions PRT disposed on a circular cylinder shaped main body along a rotation direction RD on the surface of the body portion BOD of the electronic component 100.

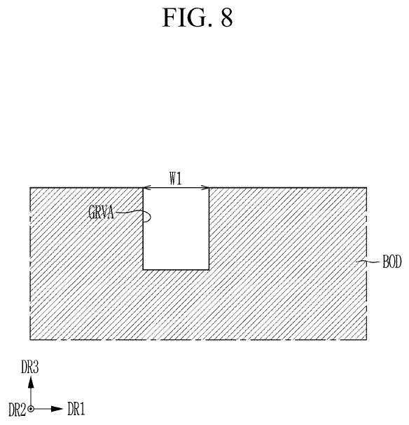

Referring to FIG. 8, the entrance portions and bottom portions of the preliminary groove GRVA may have substantially the same first width W1 therethrough.

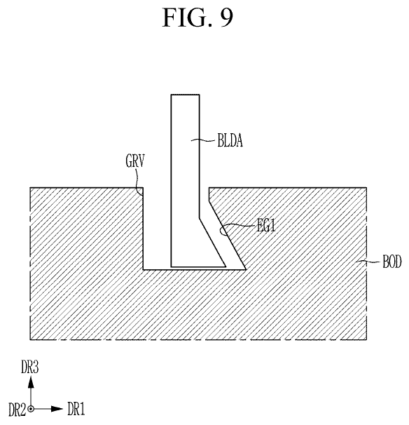

Referring to FIG. 9, using a pillar shaped second blade BLDA having an inclined surface of which an end portion is expanded, the grooves GRV having a first side wall EG1, which is a sloped wall that is inclined with respect to the surface of the body portion BOD as shown in FIG. 4, may be formed by processing the preliminary groove GRVA to expand a lower surface of the preliminary groove GRVA along the inclined surface.

The portion removed by the expanded portion of the second blade BLDA may be a lower part portion having the second width W2 of the groove GRV shown in FIG. 4, and the portion that is not removed by the second blade BLDA may be the entrance portion having the first width W1 of the groove GRV shown in FIG. 4.

In this way, using the first blade BLD and the second blade BLDA, a plurality of grooves GRV shown in FIG. 4 may be formed. The plurality of grooves GRV shown in FIG. 4 has a greater second width W2 at a lower part of the plurality of grooves GRV and a smaller first width W1 at a higher part of the plurality of grooves GRV, along the vertical direction DR33 substantially perpendicular to the surface of the body portion BOD. The plurality of grooves GRV includes a first side wall EG1, which is a sloped wall that is inclined to the surface of the body portion BOD, and a second side wall EG2, which is substantially vertical to the surface of the body portion BOD.

The electronic component 100 having a plurality of grooves GRV and the semiconductor chip 200 may be mounted on the substrate SUB.

A molding layer MOD covering the electronic component 100 and the semiconductor chip 200 may be formed on the substrate SUB on which the electronic component 100 and the semiconductor chip 200 are mounted. The molding layer MOD may fill the plurality of grooves GRV of the body portion BOD.

According to the method of manufacturing a semiconductor package according to an embodiment of the present inventive concept, a plurality of grooves GRV may be formed in the body portion BOD of the electronic component 100 of the semiconductor package 10, and the grooves GRV may have a greater second width W2 at a lower part thereof and a smaller first width W1 at an upper part thereof along the vertical direction DR33 substantially perpendicular to the surface of the body portion BOD. The second width W2 is greater than the first width W1. Therefore, the molding layer MOD can be prevented from being peeled off from the body portion BOD, and even if the metal substance SFL moves along the interface that is between the body portion BOD and the molding layer MOD, since it may be difficult for the metal substance SFL to connect to each other while passing through the groove GRV, the first external electrode EXEL1 and the second external electrode EXEL2 can be prevented from being shorted to each other.

Many features of the semiconductor packages according to the embodiments described above are all applicable to the method of manufacturing a semiconductor package according to the present embodiment.

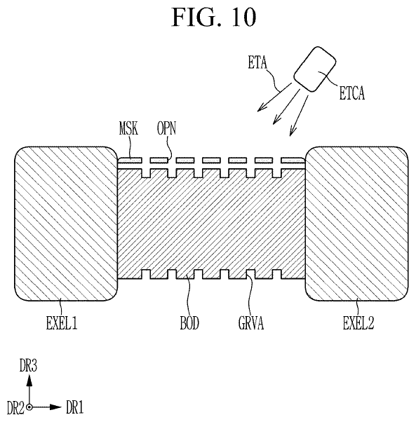

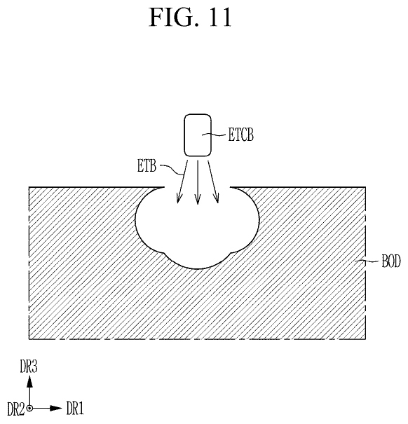

Referring to FIGS. 10 and 11 along with FIGS. 1, 2 and 4, a method of manufacturing the electronic component 100 of the semiconductor package 10 according to an embodiment of the present inventive concept will be described. FIGS. 10 and 11 are cross-sectional views illustrating a method of manufacturing an electronic component of a semiconductor package according to an embodiment of the present inventive concept.

First, an electronic component 100 including a body portion BOD, a first external electrode EXEL1 and a second external electrode EXEL2 may be formed. The first external electrode EXEL1 and the second external electrode EXEL2 may be disposed on both sides of the body portion BOD along the first direction DR1 and spaced apart from each other.

Next, as shown FIGS. 10 and 11, a plurality of grooves GRV may be formed in the body portion BOD of the electronic component 100.

Referring to FIG. 10, preliminary grooves GRVA on the surface of the body portion BOD of the electronic component 100 may be formed by first etching ETA the surface of the body portion BOD through an etching mask MSK having a plurality of openings OPN by use of a first etching apparatus ETCA.

The entrance portion and the lower part portion of the preliminary groove GRVA may have substantially the same width as each other.

The first etching (ETA) may be anisotropic etching.

Referring to FIG. 11, by second etching ETB the preliminary groove GRVA by using the second etching apparatus ETCB, a plurality of grooves GRV, as shown in FIG. 5, having a width at an upper part of the plurality of grooves GRV that is smaller than a width at a lower part of the plurality of grooves GRV along the vertical direction DR33 substantially perpendicular to the surface of the body portion BOD and including a curve-shaped first side wall EG1 and a curve-shaped second side wall EG2 may be formed.

The second etching ETB may be isotropic etching.

In this way, by using the first etching ETA and the second etching ETB, a plurality of grooves GRV, as shown in FIG. 5, having a greater second width W2 at a lower part thereof and a smaller first width W1 at an upper part thereof and including a curve-shaped first side wall EG1 and a curve-shaped second side wall EG2 may be formed.

The electronic component 100 having a plurality of grooves GRV and the semiconductor chip 200 may be mounted on the substrate SUB.

A molding layer MOD covering the electronic component 100 and the semiconductor chip 200 may be formed on the substrate SUB on which the electronic component 100 and the semiconductor chip 200 are mounted. The molding layer MOD may fill the plurality of grooves GRV of the body portion BOD.

According to the method of manufacturing a semiconductor package according to an embodiment of the present inventive concept, a plurality of grooves GRV may be formed in the body portion BOD of the electronic component 100 of the semiconductor package 10, and the grooves GRV may have a greater second width W2 at a lower part thereof and a smaller first width W1 at an upper part thereof along the vertical direction DR33 substantially perpendicular to the surface of the body portion BOD. Therefore, the molding layer MOD can be prevented from being peeled off from the body portion BOD, and even if the metal substance SFL moves along the interface that is between the body portion BOD and the molding layer MOD, since it may be difficult for the metal substance SFL to connect to each other while passing through the groove GRV, the first external electrode EXEL1 and the second external electrode EXEL2 can be prevented from being shorted to each other.

Many features of the semiconductor packages according to the embodiments described above are all applicable to the method of manufacturing a semiconductor package according to the present embodiment.

While the present inventive concept has been shown and described with reference to the embodiments thereof, it will be apparent to those of ordinary skill in the art that various changes in form and detail may be made thereto without departing from the spirit and scope of the present inventive concept.

### DESCRIPTION OF SYMBOLS

10: semiconductor package
100: electronic components
200: semiconductor chip
SUB: substrate
MOD: molding layer
BOD: body portion
EXEL1, EXEL2: external electrode
GRV: groove
SB: external contact terminal
EG1, EG2: sidewall

What is claimed is:

1. A semiconductor package comprising:
a semiconductor chip and an electronic component mounted on a substrate; and
a molding layer disposed on the substrate and covering the semiconductor chip and the electronic component,
wherein the electron component comprises a plurality of grooves, wherein the plurality of grooves are disposed on a surface of the electronic component,
wherein the plurality of grooves have a first width at an entrance portion of the plurality of grooves and a second width greater than the first width below the entrance portion, and
wherein the molding layer is disposed in the plurality of grooves.

2. The semiconductor package of claim 1, wherein
the electronic component comprises:
a body portion; and
a first external electrode and a second external electrode that are separated from each other along a first direction and connected to the body portion, wherein
the plurality of grooves are disposed on the body portion.

3. The semiconductor package of claim 2, wherein
the plurality of grooves have a shape extending in a second direction different from the first direction, and
the plurality of grooves are separated from each other along the first direction.

4. The semiconductor package of claim 3, wherein
each of the plurality of grooves has a first sidewall and a second sidewall facing each other along the first direction.

5. The semiconductor package of claim 4, wherein
at least one of the first sidewall or the second sidewall is a sloped wall that is inclined with respect to the surface of the body portion.

6. The semiconductor package of claim 5, wherein
the first sidewall and the second sidewall are sloped walls that are inclined in different directions from each other with respect to the body portion.

7. The semiconductor package of claim 5
an angle between the first sidewall and the surface of the body portion is different from an angle between the second sidewall and the surface of the body portion.

8. The semiconductor package of claim 7, wherein
the first sidewall is the sloped wall and second side wall is substantially perpendicular to the surface of the body portion.

9. The semiconductor package of claim 4, wherein
each of the first sidewall and the second sidewall have a curved surface.

10. A semiconductor package manufacturing method comprising:
forming an electronic component;
forming a plurality of grooves on a surface of the electronic component;
mounting a semiconductor chip and the electronic component on the substrate; and
forming, on the substrate, a molding layer covering the semiconductor chip and the electronic component, wherein
the plurality of grooves have a first width at an entrance portion of the grooves and a second width greater than the first width, and
the molding layer is formed in the plurality of grooves.

11. The semiconductor package manufacturing method of claim 10, wherein
the electronic component comprises:
a body portion; and
a first external electrode and a second external electrode that are separated from each other along a first direction and connected to the body portion, and
the plurality of grooves are formed on the body portion.

12. The semiconductor package manufacturing method of claim 11, wherein:
the plurality of grooves have a shape extending in a second direction that is different from the first direction, and
the plurality of grooves are separated from each other along the first direction.

13. The semiconductor package manufacturing method of claim 12, wherein
forming the plurality of grooves comprises
emitting a laser from a side of the body portion along the second direction through a laser supplying unit.

14. The semiconductor package manufacturing method of claim 13, wherein
the laser supply unit moves along the first direction to supply the laser.

15. The semiconductor package manufacturing method of claim 13, wherein
each of the plurality of grooves has a first sidewall and a second sidewall facing each other along the first direction, and
the first sidewall and the second sidewall are sloped walls that are inclined in different directions with respect to a surface of the body portion.

16. The semiconductor package manufacturing method of claim 12, wherein
forming the plurality of grooves comprises:
forming a plurality of preliminary grooves on the surface of the body portion by using a first blade; and
forming the plurality of grooves by processing the preliminary grooves by using a second blade having a different shape from the first blade.

17. The semiconductor package manufacturing method of claim 16, wherein
the first blade comprises a circular cylinder main body and a plurality of protrusions disposed on the main body,
the second blade has an inclined surface laterally expanded from a bottom surface of the second blade,
the plurality of preliminary grooves are formed by rotating the first blade along a rotation direction, and
the plurality of grooves are formed by expanding the plurality of preliminary grooves along the inclined surface.

18. The semiconductor package manufacturing method of claim 17, wherein
the first sidewall is the sloped wall, and second side wall is substantially perpendicular to the surface of the body portion.

19. The semiconductor package manufacturing method of claim 12, wherein
forming the plurality of grooves comprises:
forming a plurality of preliminary grooves by a first etching process on the surface of the body portion;
forming the plurality of grooves by processing the plurality of preliminary grooves by a second etching process that is different from the first etching process.

20. The semiconductor package manufacturing method of claim 19, wherein
each of the first sidewall and the second sidewall as a curved surface.
